(19) United States
(12) Patent Application Publication
(10) Pub. No.: US 2007/0257748 A1
(43) Pub. Date: Nov. 8, 2007

(54) ACTIVE INDUCTOR

(75) Inventor: Kazuo Kawai, Tokyo (JP)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(73) Assignee: GENERAL RESEARCH OF ELECTRONICS, INC., Tokyo (JP)

(21) Appl. No.: 11/738,161

(22) Filed: Apr. 20, 2007

(30) Foreign Application Priority Data
May 2, 2006 (JP) 2006-128350

(51) Int. Cl. H03H 11/00

(52) U.S. Cl. 333/214

(57) ABSTRACT

The present invention provides an active inductor comprising an input terminal, a primary all-pass type 90° phase-delayed stage constituted of discrete elements, and a phase inversion amplifying stage and including a constitution in which a signal supplied to the input terminal is inputted to the primary all-pass type 90° phase-delayed stage, a 90° phase-delayed signal obtained at its output is inputted to the phase inversion amplifying stage subsequent to the primary all-pass type 90° phase-delayed stage and phase-inversion amplified thereat, and an output produced from the phase inversion amplifying stage is feedback-coupled to the input terminal. The resistance value of a load resistor of the phase inversion amplifying stage is adjusted in such a manner that the signal gain between an input end of the primary all-pass type 90° phase-delayed stage and an output end of the phase inversion amplifying stage is brought to 1, whereby the active inductor is configured so as to exhibit an equivalent inductor when the inside of the active inductor is seen from the input terminal.

### BACKGROUND OF THE INVENTION

1. Field of the Invention

The present invention relates to an active inductor, and particularly to an active inductor which constitutes an inductor element whose one end is grounded, using an all-pass type 90° phase-advanced unit or an all-pass type 90° phase-delayed unit constituted of discrete elements such as a capacitor or inductor, resistors, a transistor, etc.

2. Description of the Related Art

In general, a lumped constant type filter needs to change the capacitance value of a capacitor used therein and/or the inductance value of an inductor used therein when a cut-off frequency of the lumped constant type filter and a bandwidth or the like thereof are changed. Further, when the cut-off frequency and the bandwidth are continuously changed, it is necessary to bring the lumped constant type filter to such a configuration that the capacitance value of the capacitor and/or the inductance value of the inductor can be changed within their corresponding prescribed ranges.

When the inductance value of the inductor is changed where the cut-off frequency and bandwidth of the lumped constant type filter are continuously changed, a plurality of inductors respectively having predetermined inductance values are connected and disposed within the lumped constant type filter, and an inductor connection switching means for selecting and connecting one or more of the plural inductors is used in conjunction therewith, whereby their inductance values are set so as to assume necessary values, or a desired inductance value is obtained using a generalized impedance converter (GIC).

The generalized impedance converter (GIC) employed in this case is configured by a combination of two operational amplifiers and series-connected five impedance elements Z1, Z2, Z3, Z4 and Z5. Assuming that, for example, the impedance element Z4 is configured as a capacitor and all the other impedance elements Z1, Z2, Z3 and Z5 are respectively configured as resistors using that an input impedance Z of the generalized impedance converter (GIC) comes to Z=Z1·Z3·Z5/(Z2·Z4), an active inductor in which the input impedance Z becomes an inductance value can be obtained. If the resistance values of any one or more of the resistors constituted of the impedance elements Z1, Z2, Z3 and Z5 are changed, then the magnitude of the inductance value of the active inductor can be changed.

Incidentally, since an inductance value adjusting means that prepares a plurality of fixed inductors each having a precedently required inductance value does not use all the inductors at all times, the inductors are not only low in use efficiency but also relatively high in price—to say nothing of having relatively large capacities originally. Therefore, the required capacity occupation rate and cost efficiency are poor. When inductors having inductance values different from the prepared inductance values are suddenly required, there may be no time for execution of their inductance adjustments.

On the other hand, since there is used, as the generalized impedance converter, one using the combination of the two operational amplifiers and the series-connected five impedance elements Z1, Z2, Z3, Z4 and Z5 although the lumped constant type filter configured using the generalized impedance converter can be at least simplified in circuit configuration, the degree of simplification of its circuit configuration is insufficient. Hence, there has been a demand for appearance of a generalized impedance converter more simplified in circuit configuration.

In order to overcome such inconvenience at the time of the adjustment to the inductance value, the present applicant has already proposed an active inductor that varies a resistance value thereby to make it possible to obtain an inductance value proportional to the resistance value immediately. The present applicant has applied for its patent as Japanese Patent Application No. 2006-039468.

In this case, the active inductor according to Japanese Patent Application No. 2006-039468 is configured on the basis of the following way of thinking or idea. That is, in order to configure the active inductor, an input signal current 90° phase-delayed with respect to an input signal voltage may be set so as to flow into an input terminal thereof when the input signal voltage is supplied to the input terminal. Therefore, when an input signal voltage is applied to the input terminal of the inductor, a signal 90° phase-advanced with respect to the input signal voltage, i.e., a 90° phase-advanced signal is formed and the so-formed 90° phase-advanced signal is drawn from the input terminal to the inside of the active inductor as an input signal current, thereby obtaining the active inductor.

The active inductor according to the Japanese Patent Application No. 2006-039468 has been implemented using an all-pass type 90° phase-advanced unit using op amplifiers to obtain the forms or modes of such an input signal voltage and such an input signal current. It is, however, an actual situation that a large number of op amplifiers change in characteristic depending upon usable frequencies as well known, and when frequency signals lying in a low frequency band are used, many thereof offer their performance sufficiently and can obtain required signal gain with respect to all frequency signals lying in the band, whereas when frequency signals lying in a high frequency band are used, many thereof are reduced in signal gain with the high frequencies, e.g., when the usable frequency reaches a 10 MHz band, the number of satisfactorily usable op amplifiers is considerably reduced, whereas when the usable frequency reaches a few 100 MHz bands, the satisfactorily usable ones have practically disappeared.

Due to such reasons, the active inductor according to Japanese Patent Application No. 2006-039468 is greatly restricted in its use even with respect to frequency signals lying in a VHF band—to say nothing of being restricted in its use with respect to frequency signals lying in a UHF band. It is thus difficult to use the active inductor in an ultra high-frequency band filter or the like.

### SUMMARY OF THE INVENTION

The present invention has been made in view of such a technical background. It is therefore an object of the present invention to provide an active inductor wherein a primary all-pass type 90° phase-delayed stage or 90° phase-advanced stage is formed using discrete elements without using op amplifiers, thereby making it possible to enhance a usable frequency band.

In order to attain the above object, there is provided an active inductor according to the present invention, which includes first constituting means comprising an input terminal, a primary all-pass type 90° phase-delayed stage constituted of discrete elements, and a phase inversion amplifying stage, and including a constitution in which a signal supplied to the input terminal is inputted to the primary all-pass type 90° phase-delayed stage, a 90° phase-delayed signal obtained at an output of the primary all-pass type 90° phase-delayed stage is inputted to the phase inversion amplifying stage subsequent to the primary all-pass type 90° phase-delayed stage and phase-inversion amplified thereat, and a signal outputted from the phase inversion amplifying stage is feedback—coupled to the input terminal, wherein a load resistance value of the phase inversion amplifying stage is adjusted in such a manner that a signal gain between an input end of the primary all-pass type 90° phase-delayed stage and an output end of the phase inversion amplifying stage becomes 1, whereby the first constituting means is configured so as to exhibit an equivalent inductor when the inside of the active inductor is seen from the input terminal.

Also in order to attain the above object, there is provided an active inductor according to the present invention, which includes second constituting means comprising an input terminal, a primary all-pass type 90° phase-delayed stage constituted of discrete elements, a phase inversion amplifying stage, and an inphase amplifying stage, and including a constitution in which a signal supplied to the input terminal is inputted to the primary all-pass type 90° phase-delayed stage, a 90° phase-delayed signal obtained at an output of the primary all-pass type 90° phase-delayed stage is inputted to the phase inversion amplifying stage subsequent to the primary all-pass type 90° phase-delayed stage and phase-inversion amplified thereat, a signal outputted from the phase inversion amplifying stage is supplied to the inphase amplifying stage, and a signal outputted from the inphase amplifying stage is feedback-coupled to the input terminal, wherein a load resistance of the phase inversion amplifying stage and a load resistance of the inphase amplifying stage are adjusted in such a manner that a signal gain between an input end of the primary all-pass type 90° phase-delayed stage and an output end of the inphase amplifying stage becomes 1, whereby the second constituting means is configured so as to exhibit an equivalent inductor when the inside of the active inductor is seen from the input terminal.

Further, in order to attain the above object, there is provided an active inductor according to the present invention, which includes third constituting means comprising an input terminal, a primary all-pass type 90° phase-advanced stage constituted of discrete elements, and first and second phase inversion amplifying stages cascade-connected to each other, and including a constitution in which a signal supplied to the input terminal is inputted to the primary all-pass type 90° phase-advanced stage, a 90° phase-advanced signal obtained at an output of the primary all-pass type 90° phase-advanced stage is inputted to the first phase inversion amplifying stage subsequent to the primary all-pass type 90° phase-advanced stage and phase-inversion amplified thereat, a signal outputted from the first phase inversion amplifying stage is supplied to the second phase inversion amplifying stage, and a signal outputted from the second phase inversion amplifying stage is feedback-coupled to the input terminal, wherein a load resistance value of the second phase inversion amplifying stage is adjusted in such a manner that a signal gain between an input end of the primary all-pass type 90° phase-advanced stage and an output end of the second phase inversion amplifying stage becomes 1, whereby the third constituting means is configured so as to exhibit an equivalent inductor when the inside of the active inductor is seen from the input terminal.

Furthermore, in order to attain the above object, there is provided an active inductor according to the present invention, which includes fourth constituting means comprising an input terminal, a first phase inversion amplifying stage, a primary all-pass type 90° phase-advanced stage constituted of discrete elements, and a second phase inversion amplifying stage, and including a constitution in which a signal supplied to the input terminal is inputted to the first phase inversion amplifying stage and phase-inversion amplified thereat, a signal outputted from the first phase inversion amplifying stage is inputted to the primary all-pass type 90° phase-advanced stage, a 90° phase-advanced signal obtained at an output of the primary all-pass type 90° phase-advanced stage is inputted to the second phase inversion amplifying stage subsequent to the primary all-pass type 90° phase-advanced stage and phase-inversion amplified thereat, and a signal outputted from the second phase inversion amplifying stage is feedback-coupled to the input terminal, wherein a load resistance value of the second phase inversion amplifying stage is mainly adjusted in such a manner that a signal gain between an input end of the first phase inversion amplifying stage and an output end of the second phase inversion amplifying stage becomes 1, whereby the fourth constituting means is configured so as to exhibit an equivalent inductor when the inside of the active inductor is seen from the input terminal.

Each of the active inductors according to the first through fourth constituting means is configured on the basis of the following principle. That is, an inductor is equivalent to one in which the phase of an input signal current is 90° delayed with respect to the phase of an input signal voltage. Therefore, an active inductor indicating the same phase state as the states of the phases of these input signal voltage and current is obtained using a primary all-pass type 90° phase-delayed stage or a primary all-pass type 90° phase-advanced stage constituted using discrete elements comprising a capacitor or inductor, resistors and a transistor, and one amplifying stage or plural amplifying stages accompanying the primary all-pass type 90° phase-delayed stage or the primary all-pass type 90° phase-advanced stage.

In this case, the active inductor according to the first constituting means is provided with a primary all-pass type 90° phase-delayed stage for 90° phase-delaying an input signal, and a single phase inversion amplifying stage, which are respectively cascade-connected to each other. An output signal obtained at an output end of the single phase inversion amplifying stage is feedback-coupled to an input terminal thereby to obtain the aforementioned active inductor. The active inductor according to the second constituting means is provided with a primary all-pass type 90° phase-delayed stage for 90° phase-delaying an input signal, a single phase inversion amplifying stage and a single inphase amplifying stage, which are respectively cascade-connected to one another. An output signal obtained at an output end of the single inphase amplifying stage is feedback-coupled to an input terminal thereby to obtain the above-described active inductor.

Further, the active inductor according to the third constituting means is provided with a primary all-pass type 90° phase-advanced stage for 90° phase-advancing an input signal, and first and second phase inversion amplifying stages, which are respectively cascade-connected to one another. An output signal obtained at an output end of the second phase inversion amplifying stage is feedback-coupled to an input terminal thereby to obtain the aforementioned active inductor. The active inductor according to the fourth constituting means is provided with a first phase inversion amplifying stage, a primary all-pass type 90° phase-advanced stage for 90° phase-advancing an input signal, and a second phase inversion amplifying stage, which are respectively cascade-connected to one another. An output signal obtained at an output end of the second phase inversion amplifying stage is feedback-coupled to an input terminal thereby to obtain the aforementioned active inductor.

According to the active inductor according to the present invention as described in detail above, the active inductor is constituted using a primary all-pass type 90° phase-delayed stage or a primary all-pass type 90° phase-advanced stage constituted using a capacitor or inductor, resistors and a transistor corresponding to discrete elements, and a phase inversion amplifying stage having a simple constitution or a phase inversion amplifying stage and an inphase amplifying stage respectively having simple constitutions. Therefore, advantageous effects are brought about in that as compared with this type of active inductor configured using an op amplifier in the primary all-pass type 90° phase-advanced stage, its usable frequency band can be made higher and as compared with this type of known active inductor, its circuit configuration can extensively be simplified, and further even as compared with this type of active inductor using the op amplifier, its circuit configuration can greatly be simplified, whereby the manufacturing cost can be lowered, and an active inductor small in exclusively-possessed area as the active inductor can be obtained.

Other features and advantages of the present invention will become apparent upon a reading of the attached specification.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 relates to a first embodiment of an active inductor according to the present invention and is a circuit diagram showing a configuration of its essential part;

FIG. 2 relates to a second embodiment of an active inductor according to the present invention and is a circuit diagram illustrating a configuration of its essential part;

FIG. 3 relates to a third embodiment of an active inductor according to the present invention and is a circuit diagram depicting a configuration of its essential part;

FIG. 4 relates to a fourth embodiment of an active inductor according to the present invention and is a circuit diagram showing a configuration of its essential part;

FIG. 5 relates to a fifth embodiment of an active inductor according to the present invention and is a circuit diagram illustrating a configuration of its essential part; and

FIG. 6 relates to a sixth embodiment of an active inductor according to the present invention and is a circuit diagram depicting a configuration of its essential part.

### DETAILED DESCRIPTION OF THE PREFERRED EMBODIMENTS

Preferred embodiments of the present invention will be explained hereinafter with reference to the accompanying drawings.

### First Preferred Embodiment

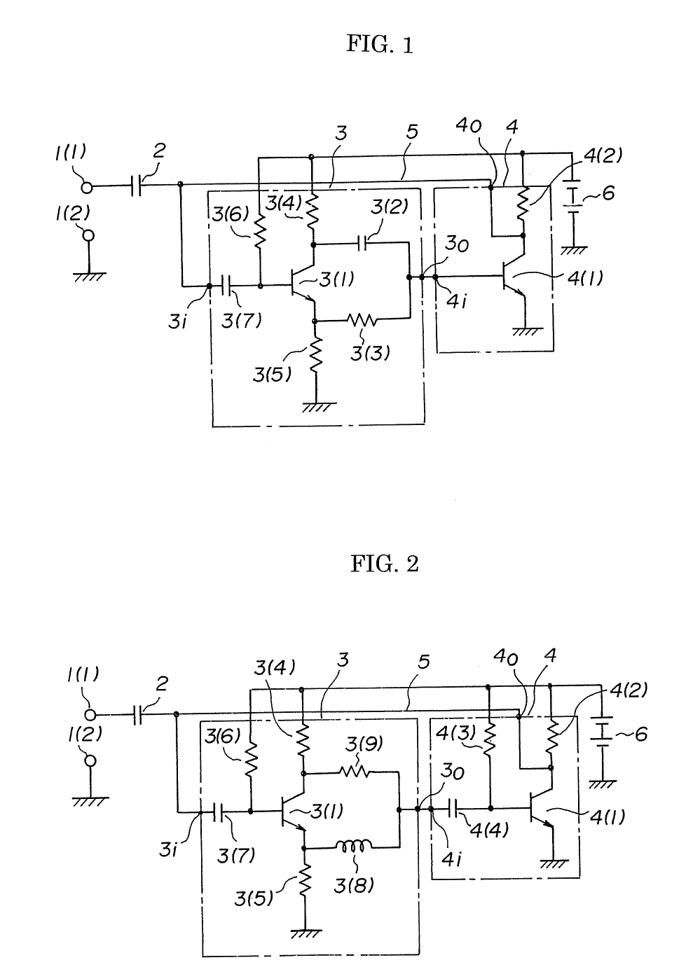

FIG. 1 relates to a first embodiment of an active inductor according to the present invention and is a circuit diagram showing a configuration of its essential part.

As shown in FIG. 1, the active inductor according to the first embodiment includes a pair of input terminals 1(1) and 1(2), a coupling capacitor 2, a primary all-pass type 90° phase-delayed stage 3, a phase inversion amplifying stage 4, a signal feedback path 5 and a DC power supply 6. One 1(1) of the pair of input terminals 1(1) and 1(2) is connected to an input end 3i of the primary all-pass type 90° phase-delayed stage 3 through the coupling capacitor 2, whereas the other 1(2) thereof is connected to ground. The primary all-pass type 90° phase-delayed stage 3 has an output end 3o connected to an input end 4i of the phase inversion amplifying stage 4. The phase inversion amplifying stage 4 has an output end 4o connected to the input end 3i of the primary all-pass type 90° phase-delayed stage 3 and the one input terminal 1(1) through the signal feedback path 5.

In this case, the primary all-pass type 90° phase-delayed stage 3 is constituted of discrete elements: a transistor 3(1), a series capacitor 3(2), a series resistor 3(3), a collector resistor 3(4), an emitter resistor 3(5), a base bias resistor 3(6) and a coupling capacitor 3(7). And the transistor 3(1) has a collector connected to the output end 3o of the primary all-pass type 90° phase-delayed stage 3 through the series resistor 3(2) and connected to the DC power supply 6 through the collector resistor 3(4), an emitter connected to the output end 3o of the primary all-pass type 90° phase-delayed stage 3 through the series capacitor 3(3) and connected to ground through the emitter resistor 3(5), and a base connected to the input end 3i of the primary all-pass type 90° phase-delayed stage 3 through the coupling capacitor 3(7) and connected to the DC power supply 6 through the base bias resistor 3(6).

The phase inversion amplifying stage 4 is constituted of a grounded-emitter transistor 4(1) and a collector load resistor 4(2). The grounded-emitter transistor 4(1) has a collector connected to the signal feedback path 5 through the output end 4o and connected to the DC power supply 6 through the collector load resistor 4(2), an emitter directly connected to ground and a base connected to the input end 4i of the phase inversion amplifying stage 4. Incidentally, the grounded-emitter transistor 4(1) shares the emitter resistor 3(5) and series resistor 3(3) of the primary all-pass type 90° phase-delayed stage 3 for its base bias resistance.

In the primary all-pass type 90° phase-delayed stage 3, the resistance value of the collector resistor 3(4) and the resistance value of the emitter resistor 3(5) are selected so as to be equal to each other. Signal gain between the input end 3i and the output end 3o is set so as to assume 1. In the phase inversion amplifying stage 4, the resistance value of the collector load resistor 4(2) of the grounded-emitter transistor 4(1) is selected so as to assume a resistance value extremely lower than the normal resistance value, e.g., a resistance value in the neighborhood of, for example, 1Ω. According to the resistance value, signal gain between the input end 4i and the output end 4o is set to 1. Therefore, the signal gain from the input end 3i of the primary all-pass type 90° phase-delayed stage 3 to the output end 4o of the phase inversion amplifying stage 4 is also set to 1.

The active inductor based on the above constitution is operated as follows:

When a high-frequency signal is supplied between the pair of input terminals 1(1) and 1(2), the high-frequency signal is supplied to the input end 3i of the primary all-pass type 90° phase-delayed stage 3 through the coupling capacitor 2. At this time, the primary all-pass type 90° phase-delayed stage 3 forms a 90° phase-delayed signal phase-delayed by 90° with respect to the input high-frequency signal at the output end 3o in the form of the same signal level (signal gain 1) as the input high-frequency signal by means of a collector-emitter signal dividing circuit constituted of the transistor 3(1) and the collector resistor 3(4) and emitter resistor 3(5) each having the same resistance value and a phase-delayed circuit constituted of the series capacitor 3(2) and the series resistor 3(3). Thereafter, the 90° phase-delayed signal is supplied to the phase inversion amplifying stage 4 subsequent to the primary all-pass type 90° phase-delayed stage 3. The phase inversion amplifying stage 4 phase-inversion amplifies the 90° phase-delayed signal at the same signal level (signal gain 1) by means of the grounded-emitter transistor 4(1) and thereby forms a 90° phase-advanced signal at the collector. The 90° phase-advanced signal is supplied from the output end 4o to the input end 3i of the primary all-pass type 90° phase-delayed stage 3 and the input terminal 1(1) at the same signal level as the level of the input high-frequency signal through the signal feedback path 5. With the provision of such configuration means, the inside of the active inductor leads to a signal state equivalent to the flow of the 90° phase-delayed signal into the input terminal 1(1) when the inside thereof is viewed from the input terminal 1(1). Thus, an equivalent inductor is formed between the input terminals 1(1) and 1(2).

The background to the formation of the active inductor (equivalent inductor) between the input terminals 1(1) and 1(2) will be explained below in combination with equations.

A high-frequency signal current that flows into the input terminal 1(1) flows through both the collector load resistor 4(2) and an internal resistance (collector-emitter path or passage) of the grounded-emitter transistor 4(1) via the output end 4o of the phase inversion amplifying stage 4. Since, at this time, the resistance value of the collector load resistor 4(2) is set to the extremely small resistance value, e.g., the resistance value in the neighborhood of 1Ω such that the signal gain between the input end 3i of the primary all-pass type 90° phase-delayed stage 3 and the output end 4o of the phase inversion amplifying stage 4 becomes 1, the relationship that the resistance value of the collector load resistor 4(2) becomes extremely smaller than the internal resistance of the grounded-emitter transistor 4(1) is established. Thus, the majority of the high-frequency signal current having flowed into the input terminal 1(1) flows through the collector load resistor 4(2).

In the primary all-pass type 90° phase-delayed stage 3, the signal transfer function H1(s) is expressed in the following equation (1) as well known when the high-frequency signal gain is 1:

$$H 1 ( s ) = \frac{s - \frac{1}{CoRo}}{s + \frac{1}{CoRo}} \qquad ( 1 )$$

In the above equation (1), s indicates a Laplace transformer, and C0 and R0 respectively indicate the capacitance value of the series capacitor 3(2) and the resistance value of the series resistor 3(3) both of which constitute the phase-delayed circuit.

In the phase inversion amplifying stage 4 of the following stage, the signal transfer function between the input end 3i of the primary all-pass type 90° phase-delayed stage 3 and the output end 40 of the phase inversion amplifying stage 4 results in one obtained by phase-inverting the signal transfer function H1(s) expressed in the equation (1) when the high-frequency signal gain is 1.

At this time, the primary all-pass type 90° phase-delayed stage 3 generates a 90° phase-delayed signal phase-delayed by 90° with respect to the input signal at a frequency at which R0=(1/ωC0) in the equation (1). When the 90° phase-delayed signal is supplied to the phase inversion amplifying stage 4 of the following stage and phase-inversion amplified by the phase inversion amplifying stage 4, its output signal becomes a 90° phase-advanced signal. When the 90° phase-advanced signal is supplied to the input terminal 1(1) through the signal feedback path 5, the input signal current is brought into a sucked state by the 90° phase-advanced signal. If, however, this is viewed toward the inside of the active inductor from the input terminal 1(1), then a high-frequency signal current phase-delayed by 90° with respect to a high-frequency signal voltage supplied to the input terminal 1(1) flows.

Assuming now that the high-frequency signal voltage applied to the input terminal 1(1) is e, the resistance value of the collector load resistor 4(2) of the phase inversion amplifying stage 4 is R4, and the current flowing through the collector load resistor 4(2) is i, the current i is expressed in the following equation (2):

$$i = \frac{e 1 [ 1 + \frac{s - \frac{1}{CoRo}}{s + \frac{1}{CoRo}} ]}{R 4} \qquad ( 2 )$$

Determining the input impedance (e/i) of the active inductor as viewed from the input terminal 1(1) from the equation (2) yields the following equation (3) by transformation of the equation (2):

$$\frac{e 1}{i} = \frac{R 4}{2} + s \frac{CoRoR 4}{2} \qquad ( 3 )$$

As expressed in the equation (3), the thus-obtained active inductor (equivalent inductor) is brought to a combined inductance value indicated by the sum of (sC0R0R4/2) indicative of an inductor component and (R4/2) indicative of a small or micro resistive component.

### Second Preferred Embodiment

Next, FIG. 2 relates to a second embodiment of an active inductor according to the present invention and is a circuit diagram showing a configuration of its essential part. Comparing the active inductor according to the second embodiment with the active inductor according to the first embodiment, part of the configuration of the primary all-pass type 90° phase-delayed stage 3 and part of the configuration of the phase inversion amplifying stage 4 merely differ respectively. Other configurations excluding the primary all-pass type 90° phase-delayed stage 3 and the phase inversion amplifying stage 4 are identical. Incidentally, the same constituent elements as those shown in FIG. 1 are given the same reference numerals in FIG. 2.

That is, the primary all-pass type 90° phase-delayed stage 3 according to the second embodiment includes a series inductor 3(8) and a series resistor 3(9) in addition to the provision of a transistor 3(1), a collector resistor 3(4), an emitter resistor 3(5), a base bias resistor 3(6) and a coupling capacitor 3(7). They are all constituted of discrete elements. The primary all-pass type 90° phase-delayed stage 3 functionally performs the same function as that of the primary all-pass type 90° phase-delayed stage 3 according to the first embodiment. The series inductor 3(8) is connected between the emitter of the transistor 3(1) and an output end 3o. The series resistor 3(9) is connected between the collector of the transistor 3(1) and the output end 3o. They are reversed in their connecting positions as compared with the states of connections of the series capacitor 3(2) and series resistor 3(3) of the primary all-pass type 90° phase-delayed stage 3 according to the first embodiment.

The phase inversion amplifying stage 4 according to the second embodiment includes a base bias resistor 4(3) and a coupling capacitor 4(4) in addition to the provision of a grounded-emitter transistor 4(1) and a collector load resistor 4(2) having an extremely small resistance value. The phase inversion amplifying stage 4 functionally performs the same function as that of the phase inversion amplifying stage 4 according to the first embodiment. The base bias resistor 4(3) is connected between the base of the grounded-emitter transistor 4(1) and a DC power supply 6. The coupling capacitor 4(4) is connected between the base of the grounded-emitter transistor 4(1) and an input end 4i.

Since the operation of the active inductor according to the second embodiment is almost the same as that of the active inductor according to the first embodiment, further explanations about the operation of the active inductor according to the second embodiment are omitted. Assuming that even in this case, a high-frequency signal voltage applied to an input terminal 1(1) is e, the inductance value of the series inductor 3(8) of the primary all-pass type 90° phase-delayed stage 3 is L0, the resistance value of the series resistor 3(9) is R0, the resistance value of the collector load resistor 4(2) of the phase inversion amplifying stage 4 is R4, and the current flowing through the collector load resistor 4(2) is i, its input impedance (e/i) is given as expressed in the following equation (4):

$$\frac{e 1}{i} = \frac{R 4}{2} + s \frac{LoR 4}{2 Ro} \qquad ( 4 )$$

As expressed in the equation (4), the thus-obtained active inductor (equivalent inductor) is brought to a combined inductance value indicated by the sum of (sL0R4/2R0) indicative of an equivalent inductor component and (R4/2) indicative of a small or micro resistive component.

### Third Preferred Embodiment

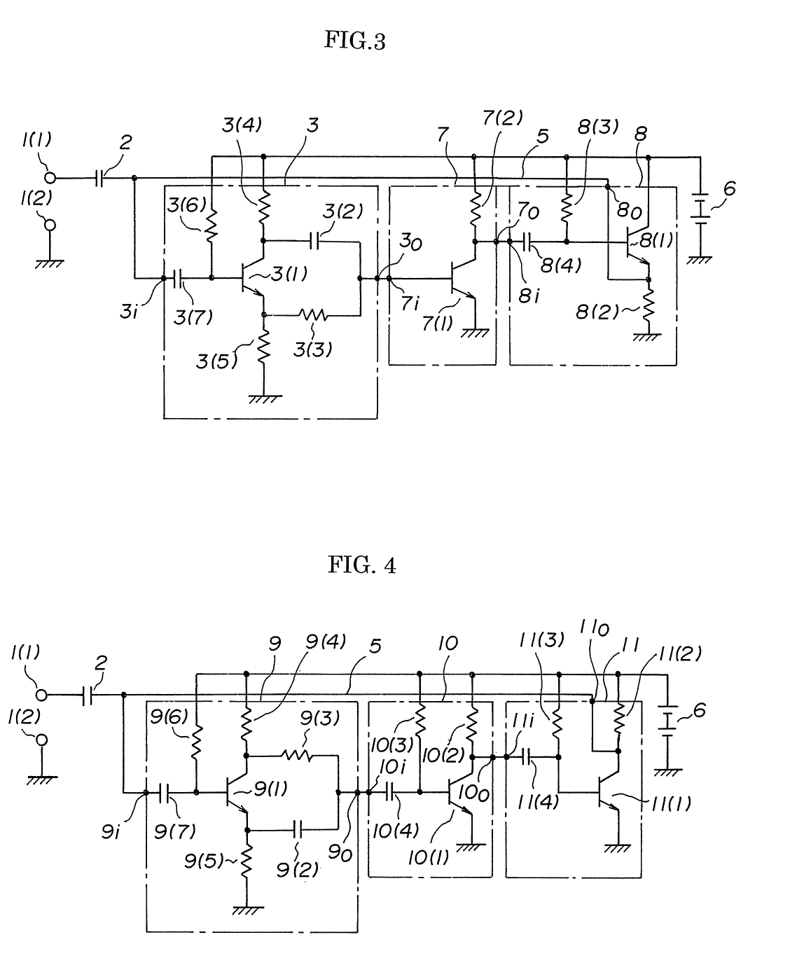

Next, FIG. 3 relates to a third embodiment of an active inductor according to the present invention and is a circuit diagram showing a configuration of its essential part. Comparing the active inductor according to the third embodiment with the active inductor according to the first embodiment, they are merely different in configuration from each other in that an inphase amplifying stage 8 is cascade-connected to the output side of a phase inversion amplifying stage 7, and a signal feedback path 5 is connected to an output end of the inphase amplifying stage 8. The configuration other than this is identical to the configuration of the active inductor according to the first embodiment. Incidentally, in FIG. 3, the same symbols are attached to the same constituent elements as those shown in FIG. 1.

The phase inversion amplifying stage 7 according to the third embodiment includes a grounded-emitter transistor 7(1) and a collector load resistor 7(2) and is identical in configuration to the phase inversion amplifying stage 4 according to the first embodiment except that the resistance value of the collector load resistor 7(2) is set to a value higher than the resistance value of the collector load resistor 4(2) according to the first embodiment. The function of the phase inversion amplifying stage 7 is also approximately the same as in the phase inversion amplifying stage 4 except that the signal gain is greater than or equal to 1. The inphase amplifying stage 8 according to the third embodiment includes an emitter follower transistor 8(1), an emitter load resistor 8(2) having a resistance value considerably lower than the normal resistance value, e.g., a resistance value in the neighborhood of 1 Ω, a base bias resistor 8(3) and a coupling capacitor 8(4). The emitter follower transistor 8(1) has an emitter connected to ground through the emitter load resistor 8(2) and connected to the signal feedback path 5 through the output end 8o, a collector directly connected to a DC power supply 6, and a base connected to the DC power supply 6 through the base bias resistor 8(3) and connected to an input end 8i through the coupling capacitor 8(4).

In the third embodiment, the resistance value of the collector load resistor 7(2) and the resistance value of the emitter load resistor 8(2) are respectively selected suitably to thereby set the total signal gain of the phase inversion amplifying stage 7 and the inphase amplifying stage 8 to 1 and set the resistance value of the emitter load resistor 8(2) of the inphase amplifying stage 8 to the value in the neighborhood of 1Ω, whereby the active inductor is caused to have the same function as that of the phase inversion amplifying stage 4 according to the first embodiment by virtue of the phase inversion amplifying stage 7 and the inphase amplifying stage 8. Since the operation of the active inductor according to the third embodiment is also almost the same as the operation of the active inductor according to the first embodiment, further explanations about the operation of the active inductor according to the third embodiment are omitted.

In a manner similar to the above case in the third embodiment, the thus-obtained active inductor (equivalent inductor) is brought to a combined inductance value indicated by the sum of (sL0R8/2R0) indicative of an inductor component and (R8/2) indicative of a small or micro resistive component assuming that the capacitance value of a series capacitor 3(2) of a primary all-pass type 90° phase-delayed stage 3 is 0, the resistance value of a series resistor 3(3) is R0 and the resistance value of the emitter load resistor 8(2) of the inphase amplifying stage 8 is R8.

### Fourth Preferred Embodiment

Subsequently, FIG. 4 relates to a fourth embodiment of an active inductor according to the present invention and is a circuit diagram showing a configuration of its essential part. Comparing the active inductor according to the fourth embodiment with the active inductor according to the first embodiment, a primary all-pass type 90° phase-advanced stage 9 is used in place of the primary all-pass type 90° phase-delayed stage 3, and a first phase inversion amplifying stage 10 and a second phase inversion amplifying stage 11 cascade-connected to each other are used in place of the use of the single phase inversion amplifying stage 4 in conjunction with the primary all-pass type 90° phase-advanced stage 9. Incidentally, in FIG. 4, the same symbols are attached to the same constituent elements as those shown in FIG. 1.

In this case, the primary all-pass type 90° phase-advanced stage 9 is constituted of discrete elements: a transistor 9(1), a series capacitor 9(2), a series resistor 9(3), a collector resistor 9(4), an emitter resistor 9(5), a base bias resistor 9(6) and a coupling capacitor 9(7). The transistor 9(1) has a collector connected to an output end 9o of the primary all-pass type 90° phase-advanced stage 9 through the series capacitor 9(3) and connected to a DC power supply 6 through the collector resistor 9(4), an emitter connected to the output end 9o of the primary all-pass type 90° phase-advanced stage 9 through the series capacitor 9(2) and connected to ground through the emitter resistor 9(5), and a base connected to an input end 9i of the primary all-pass type 90° phase-advanced stage 9 through the coupling capacitor 9(7) and connected to the DC power supply 6 through the base bias resistor 9(6).

The first phase inversion amplifying stage 10 includes a grounded-emitter transistor 10(1), a collector load resistor 10(2), a base bias resistor 10(3) and a coupling capacitor 10(4). The grounded—emitter transistor 10(1) has a collector connected to an output end 10o and connected to the DC power supply 6 through the collector load resistor 10(2), an emitter connected to ground and a base connected to the DC power supply 6 through the base bias resistor 10(3) and connected to an input end 10i through the coupling capacitor 10(4).

Further, the second phase inversion amplifying stage 11 includes a grounded-emitter transistor 11(1), a collector load resistor 11(2), a base bias resistor 11(3) and a coupling capacitor 11(4). The grounded-emitter transistor 11(1) has a collector connected to a signal feedback path 5 through an output end 11o and connected to the DC power supply 6 through the collector load resistor 11(2), an emitter connected to ground and a base connected to the DC power supply 6 through the base bias resistor 11(3) and connected to an input end 11i through the coupling capacitor 10(4).

In the active inductor according to the fourth embodiment, the resistance value of the collector load resistor 10(2) of the first phase inversion amplifying stage 10 and the resistance value of the collector load resistor 11(2) of the second phase inversion amplifying stage 11 are set as follows. First, the resistance value of the collector load resistor 11(2) of the second phase inversion amplifying stage 11 is set to a resistance value extremely lower than the normal resistance value, e.g., a resistance value in the neighborhood of 1Ω. Thereafter, the resistance value of the collector load resistor 10(2) of the first phase inversion amplifying stage 10 is set to such a resistance value that the total signal gain of the first phase inversion amplifying stage 10 and the second phase inversion amplifying stage 11 is brought to 1.

The active inductor according to the fourth embodiment produces a 90° phase-advanced signal at the output end 9o of the primary all-pass type 90° phase-advanced stage 9 using the primary all-pass type 90° phase-advanced stage 9 in place of the primary all-pass type 90° phase-delayed stage 3. Thus, the active inductor phase-inversion amplifies the 90° phase-advanced signal twice through the first phase inversion amplifying stage 10 and the second phase inversion amplifying stage 11 and outputs the amplified 90° phase-advanced signal to the output end 11o of the second phase inversion amplifying stage 11. Since the basic operation of the active inductor is identical to the operations of the active inductors according to the first through third embodiments as already stated, further explanations about the operation of the active inductor according to the fourth embodiment are omitted.

In the active inductor according to the fourth embodiment, the 90° phase-advanced signal obtained by the primary all-pass type 90° phase-advanced stage 9 is phase-inversion amplified at a signal gain of 1 by the first phase inversion amplifying stage 10 and the second phase inversion amplifying stage 11. Since the resistance value of the collector load resistor 10(2) is adjusted and set as well as the adjustment and setting of the resistance value of the collector load resistor 11(2) upon setting the signal gain 1, the degree of freedom for the setting of the resistance value of the collector load resistor 11(2) of the second phase inversion amplifying stage 11 becomes relatively high, so that the resistance value R11 of the collector load resistor 11(2) can be set to a considerably low value. Therefore, (R11/2) indicative of a micro or small resistive component of the obtained active inductor (equivalent inductor) can be made smaller, thus making it possible to obtain a combined inductance value less reduced in micro resistive component.

### Fifth Preferred Embodiment

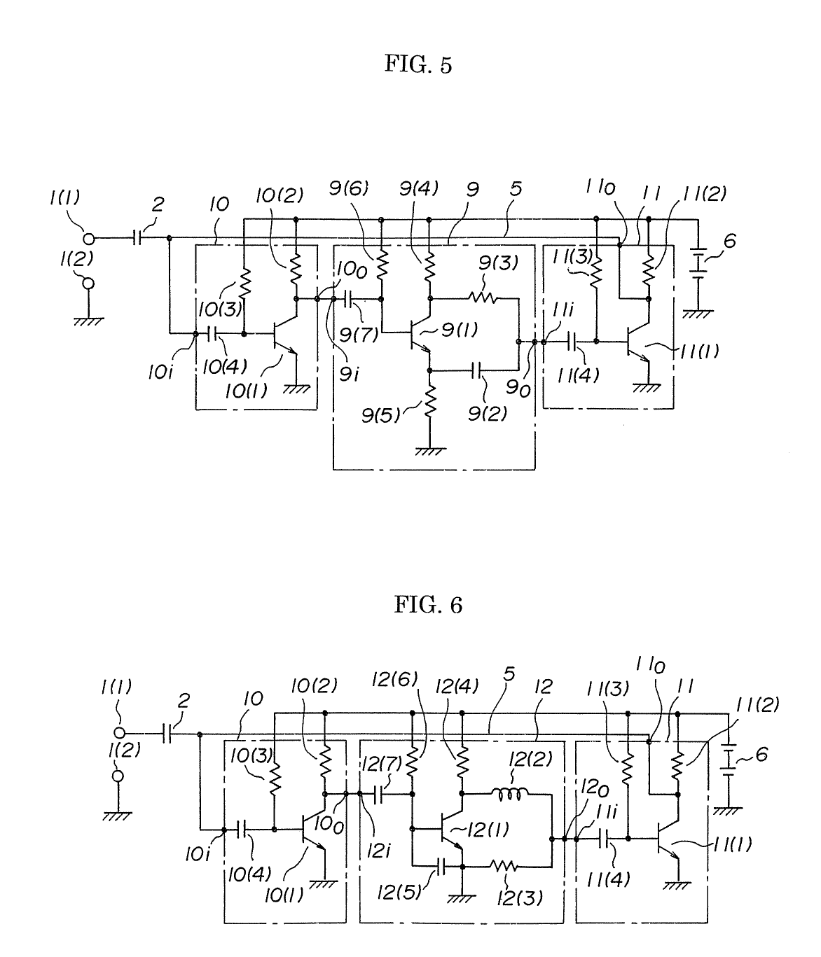

Subsequently, FIG. 5 relates to a fifth embodiment of an active inductor according to the present invention and is a circuit diagram showing a configuration of its essential part. Comparing the active inductor according to the fifth embodiment with the active inductor according to the fourth embodiment, a first phase inversion amplifying stage 10 is disposed with being connected to a stage prior to a primary all-pass type 90° phase-advanced stage 9 as an alternative to the use of the cascade-connected first phase inversion amplifying stage 10 and second phase inversion amplifying stage 11 in a stage subsequent to the primary all-pass type 90° phase-advanced stage 9, and a second phase inversion amplifying stage 11 is disposed with being connected to a stage subsequent to the primary all-pass type 90° phase-advanced stage 9. The configuration other than the above is identical to the configuration of the active inductor according to the fourth embodiment. Incidentally, in FIG. 5, the same symbols are attached to the same constituent elements as those shown in FIG. 4.

That is, the active inductor according to the fifth embodiment is one wherein the primary all-pass type 90° phase-advanced stage 9 is connected to the output side of the first phase inversion amplifying stage 10 and the second phase inversion amplifying stage 11 is connected to the output side of the primary all-pass type 90° phase-advanced stage 9. The respective configurations of the first phase inversion amplifying stage 10, the primary all-pass type 90° phase-advanced stage 9 and the second phase inversion amplifying stage 11 are identical to the configurations of the first phase inversion amplifying stage 10, the primary all-pass type 90° phase-advanced stage 9 and the second phase inversion amplifying stage 11 according to the fourth embodiment. The operation of the active inductor according to the fifth embodiment is slightly different from the operation of the active inductor according to the fourth embodiment that the high-frequency signal is 90° phase-advanced and thereafter phase-inversion amplified, in that the high-frequency signal is phase-inversion amplified prior to being 90° phase-advanced. However, the active inductor according to the fifth embodiment is identical in basic operation to the active inductor according to the fourth embodiment. Therefore, further explanations about the operation of the active inductor according to the fifth embodiment are omitted.

Incidentally, even in the case of the active inductor according to the fifth embodiment, the high-frequency signal is phase-inversion amplified at a signal gain of 1 by the first phase inversion amplifying stage 10 and the second phase inversion amplifying stage 11 in a manner similar to the active inductor according to the fourth embodiment. Since the resistance value of a collector load resistor 10(2) is adjusted and set as well as the adjustment and setting of the resistance value of a collector load resistor 11(2) upon setting the signal gain 1, the degree of freedom for the setting of the resistance value of the collector load resistor 11(2) of the second phase inversion amplifying stage 11 becomes relatively high, so that the resistance value R11 of the collector load resistor 11(2) can be set to a considerably low value. Consequently, (R11/2) indicative of a micro or small resistive component of the obtained active inductor (equivalent inductor) can be made smaller, thus making it possible to obtain a combined inductance value less reduced in micro resistive component.

### Sixth Preferred Embodiment

Next, FIG. 6 relates to a sixth embodiment of an active inductor according to the present invention and is a circuit diagram showing a configuration of its essential part. When the active inductor according to the sixth embodiment is compared with the active inductor according to the fifth embodiment, the former is merely slightly different in internal circuit from the latter in that a primary all-pass type 90° phase-advanced stage 12 with no collector-emitter dividing circuit is used in place of the use of the primary all-pass type 90° phase-advanced stage 9 provided with the collector-emitter dividing circuit. The configuration other than this is identical to the configuration of the active inductor according to the fifth embodiment. Incidentally, in FIG. 6, the same symbols are attached to the same constituent elements as those shown in FIG. 5.

That is, the primary all-pass type 90° phase-advanced stage 12 according to the sixth embodiment comprises discrete elements: a grounded-emitter transistor 12(1), a series inductor 12(2), a series resistor 12(3), a collector resistor 12(4), a DC blocking capacitor 12(5), a base bias resistor 12(6) and a coupling capacitor 12(7). The transistor 12(1) has a collector connected to an output end 12o of the primary all-pass type 90° phase-advanced stage 12 through the series inductor 12(2) and connected to a DC power supply 6 through the collector resistor 12(4), an emitter directly connected to ground and a base connected to the output end 12o through the DC blocking capacitor 12(5) and the series inductor 12(2) and connected to the DC power supply 6 through the base bias resistor 12(6), and further connected to an input end 12i through the coupling capacitor 12(7).

The primary all-pass type 90° phase-advanced stage 12 makes use of the grounded-emitter transistor 12(1) of which the collector and base are connected with the series inductor 12(2) and series resistor 12(3) that constitute a phase-delayed circuit, thereby making it possible to output a 90° phase-advanced signal obtained by 90° phase-advancing an input high-frequency signal from the output of the phase-advanced circuit. The function of the primary all-pass type 90° phase-advanced stage 12 is almost identical to the function of the primary all-pass type 90° phase-advanced stage 9 according to the fourth or fifth embodiment. Since the basic operation of the active inductor according to the sixth embodiment is identical to the operation of the active inductor according to the fifth embodiment, further explanations about the operation of the active inductor according to the sixth embodiment are omitted.

Even in the active inductor according to the sixth embodiment, the high-frequency signal is phase-inversion amplified at a total signal gain of 1 by a first phase inversion amplifying stage 10 and a second phase inversion amplifying stage 11 in a manner similar to the active inductor according to the fourth or fifth embodiment. Since the resistance value of a collector load resistor 10(2) is adjusted and set as well as the adjustment and setting of the resistance value of a collector load resistor 11(2) upon setting the signal gain 1, the degree of freedom for the setting of the resistance value of the collector load resistor 11(2) of the second phase inversion amplifying stage 11 becomes relatively high, so that the resistance value R11 of the collector load resistor 11(2) can be set to a considerably low value. Thus, (R11/2) indicative of a micro or small resistive component of the obtained active inductor (equivalent inductor) can be made smaller, thus making it possible to obtain a combined inductance value less reduced in micro resistive component.

In any of the active inductors according to the first through sixth embodiments, each of the resistance values R0 of the series resistors 3(3), 9(3) and 12(3) respectively used in the phase-delayed circuit of the primary all-pass type 90° phase-delayed stage 3 and the phase-advanced circuits of the primary all-pass type 90° phase-advanced stages 9 and 12 is contained in the obtained inductor component. Therefore, if each of the series resistors 3(3), 9(3) and 12(3) is constituted by a variable resistor, it is then possible to cause the active inductor to function as a variable inductor in which an inductance value proportional to a change in the resistance value R0 can be obtained by changing the resistance value R0 under the control of the variable resistor.

While the preferred forms of the present invention have been described, it is to be understood that modifications will be apparent to those skilled in the art without departing from the spirit of the invention. The scope of the invention is to be determined solely by the following claims.

What is claimed is:

1. An active inductor comprising:
an input terminal;
a primary all-pass type 90° phase-delayed stage constituted of discrete elements; and
a phase inversion amplifying stage,
said active inductor including a constitution in which a signal supplied to the input terminal is inputted to the primary all-pass type 90° phase-delayed stage, a 90° phase-delayed signal obtained at an output of the primary all-pass type 90° phase-delayed stage is inputted to the phase inversion amplifying stage subsequent to the primary all-pass type 90° phase-delayed stage and phase-inversion amplified thereat, and a signal outputted from the phase inversion amplifying stage is feedback-coupled to the input terminal,
wherein a load resistance value of the phase inversion amplifying stage is adjusted in such a manner that a signal gain between an input end of the primary all-pass type 90° phase-delayed stage and an output end of the phase inversion amplifying stage is brought to 1, whereby the active inductor is configured so as to exhibit an equivalent inductor when the inside of the active inductor is seen from the input terminal.

2. An active inductor comprising:
an input terminal;
a primary all-pass type 90° phase-delayed stage constituted of discrete elements;
a phase inversion amplifying stage; and
an inphase amplifying stage,
said active inductor including a constitution in which a signal supplied to the input terminal is inputted to the primary all-pass type 90° phase-delayed stage, a 90° phase-delayed signal obtained at an output of the primary all-pass type 90° phase-delayed stage is inputted to the phase inversion amplifying stage subsequent to the primary all-pass type 90° phase-delayed stage and phase-inversion amplified thereat, a signal outputted from the phase inversion amplifying stage is supplied to the inphase amplifying stage, and a signal outputted from the inphase amplifying stage is feedback-coupled to the input terminal,
wherein a load resistance of the phase inversion amplifying stage and a load resistance of the inphase amplifying stage are adjusted in such a manner that a signal gain between an input end of the primary all-pass type 90° phase-delayed stage and an output end of the inphase amplifying stage is brought to 1, whereby the active inductor is configured so as to exhibit an equivalent inductor when the inside of the active inductor is seen from the input terminal.

3. An active inductor comprising:
an input terminal;
a primary all-pass type 90° phase-advanced stage constituted of discrete elements; and
first and second phase inversion amplifying stages cascade-connected to each other,
said active inductor including a constitution in which a signal supplied to the input terminal is inputted to the primary all-pass type 90° phase-advanced stage, a 90° phase-advanced signal obtained at an output of the primary all-pass type 90° phase-advanced stage is inputted to the first phase inversion amplifying stage subsequent to the primary all-pass type 90° phase-advanced stage and phase-inversion amplified thereat, a signal outputted from the first phase inversion amplifying stage is supplied to the second phase inversion amplifying stage, and a signal outputted from the second phase inversion amplifying stage is feedback-coupled to the input terminal,
wherein a load resistance value of the second phase inversion amplifying stage is adjusted in such a manner that a signal gain between an input end of the primary all-pass type 90° phase-advanced stage and an output end of the second phase inversion amplifying stage is brought to 1, whereby the active inductor is configured so as to exhibit an equivalent inductor when the inside of the active inductor is seen from the input terminal.

4. An active inductor comprising:
an input terminal;
a first phase inversion amplifying stage;
a primary all-pass type 90° phase-advanced stage constituted of discrete elements; and
a second phase inversion amplifying stage,
said active inductor including a constitution in which a signal supplied to the input terminal is inputted to the first phase inversion amplifying stage and phase-inversion amplified thereat, a signal outputted from the first phase inversion amplifying stage is inputted to the primary all-pass type 90° phase-advanced stage, a 90° phase-advanced signal obtained at an output of the primary all-pass type 90° phase-advanced stage is inputted to the second phase inversion amplifying stage subsequent to the primary all-pass type 90° phase-advanced stage and phase-inversion amplified thereat, and a signal outputted from the second phase inversion amplifying stage is feedback-coupled to the input terminal,
wherein a load resistance value of the second phase inversion amplifying stage is mainly adjusted in such a manner that a signal gain between an input end of the first phase inversion amplifying stage and an output end of the second phase inversion amplifying stage is brought to 1, whereby the active inductor is configured so as to exhibit an equivalent inductor when the inside of the active inductor is seen from the input terminal.
